(19) United States
(12) Patent Application Publication
(10) Pub. No.: US 2025/0153385 A1
(43) Pub. Date: May 15, 2025

(54) CUTTING BLADE

(71) Applicant: DISCO CORPORATION, Tokyo (JP)

(72) Inventor: Keiichi KAI, Tokyo (JP)

(21) Appl. No.: 18/544,868

(22) Filed: Dec. 19, 2023

(30) Foreign Application Priority Data
Nov. 11, 2023 (JP) 2023-002402

(51) Int. Cl. B26D 7/26

(52) U.S. Cl. CPC B26D 7/2621

(57) ABSTRACT

A cutting blade includes a hub having a raised portion, an annular blade having an opening with the raised portion inserted in the opening, and an annular fixing member fixing the blade on the hub. The blade is sandwiched between the hub and the fixing member that is fixed on the raised portion.

### BACKGROUND OF THE INVENTION

### Field of the Invention

The present invention relates to a cutting blade that cuts a workpiece.

### Description of the Related Art

By dividing a wafer on which a plurality of devices are formed into individual pieces, chips (device chips) including the respective devices are manufactured. Further, a package substrate is formed by covering and encapsulating a plurality of device chips which are mounted on a predetermined substrate, with a resin layer (molding resin). Package devices with the packaged device chips included separately in the respective package devices are manufactured by dividing the package substrate to singulate it into individual pieces. Such device chips and package devices are incorporated in various electronic equipment such as mobile phones and personal computers.

For dividing a workpiece such as a wafer or a package substrate, a cutting apparatus is used. The cutting apparatus includes a chuck table that holds the workpiece thereon, and a cutting unit that applies cutting processing to the workpiece. The cutting unit includes a spindle, and on a distal end portion of the spindle, a blade mount is fixed to support an annular cutting blade. By mounting the cutting blade on the blade mount and causing the cutting blade to cut into the workpiece with the spindle being rotated, the workpiece is cut and divided.

As the cutting blade that cuts the workpiece, a hub-type cutting blade (hub blade) or a washer-type cutting blade (washer blade, or hubless blade) is used. The hub blade has a structure in which an annular hub and an annular blade formed along an outer peripheral edge of the hub are integrated. The blade of the hub blade is configured by an electroformed grinding stone which contains abrasive grits, and a bonding material such as a nickel plating layer that fixes the abrasive grits. Meanwhile, the washer blade is configured by only an annular blade, which contains abrasive grits and a bonding material made of metal, ceramics, resin, or the like and fixing the abrasive grits.

When cutting a workpiece by the cutting apparatus, an appropriate cutting blade is selected according to the material of the workpiece, the purpose of processing the workpiece, and the like, and is mounted on the cutting unit. However, the hub blade and the washer blade are different in the mounting method on the blade mount, and the blade mount is also different in shape, size, and the like according to the type of the cutting blade. When the hub blade which is mounted on the cutting unit is replaced with the washer blade, for example, a need therefore arises for work to replace a hub blade mount which is fixed on the spindle with a washer blade mount. This makes the cutting blade replacement work cumbersome. A method has hence been proposed to use a cutting blade (a blade with a hub) in which a washer blade is fixed on an annular hub (see JP 2012-135833 A). The use of such a blade with a hub enables to mount a washer blade on a hub blade mount, and hence simplifies the replacement work of the cutting blade.

### SUMMARY OF THE INVENTION

The cutting blade (the blade with the hub), in which the hub and the blade (washer blade) are integrated together, is manufactured by joining the hub and blade, which have been formed individually, together via an adhesive. Described specifically, over the entirety of a region of the hub where the hub is to come into contact with the blade, the adhesive is applied in an amount sufficient to surely fix the blade on the hub. Subsequently, the hub and the blade are bonded together via the adhesive.

Nonetheless, when a substantial amount of the adhesive is applied to the hub, the adhesive spreads between the hub and the blade when they are bonded together and may run over the joined region. In this case, the adhesive sticks an outer peripheral portion of the blade, and may hence cause inconvenience such that the adhesive adversely affects the processing or the blade looks less nice, resulting in a cutting blade of lowered quality. If the amount of the adhesive is decreased to prevent the adhesive from running over, on the other hand, the hub and the blade are prone to separate from each other during processing of a workpiece, thereby causing processing failure or damage to the cutting blade. Moreover, depending on the materials, sizes, weights, and the like of the hub and the blade, the firm fixing of the blade on the hub with the adhesive alone may be difficult.

The present invention has been made in view of such circumstances and has an object to provide a cutting blade that enables a hub and a blade together to be firmly integrated with the adhesive omitted or reduced in amount.

In accordance with an aspect of the present invention, there is provided a cutting blade including a hub having a raised portion, an annular blade having an opening with the raised portion inserted therein, and an annular fixing member fixing the blade on the hub. The blade is sandwiched between the hub and the fixing member that is fixed on the raised portion.

Preferably, the raised portion may include a groove with the fixing member fitted therein. Also preferably, the fixing member may be an annular resilient member having a pair of end portions that are apart from each other.

In the cutting blade according to the aspect of the present invention, the blade is sandwiched between the hub and the fixing member that is fixed on the raised portion. This enables the hub and the blade to firmly be integrated together with the adhesive for fixing the blade on the hub being omitted or reduced in amount.

The above and other objects, features and advantages of the present invention and the manner of realizing them will become more apparent, and the invention itself will best be understood from a study of the following description and appended claims with reference to the attached drawings depicting a preferred embodiment of the invention.

### BRIEF DESCRIPTION OF THE DRAWINGS

FIG. 1 is an exploded perspective view depicting a cutting blade according to an embodiment of the present invention;

FIG. 2A is a fragmentary cross-sectional view of the cutting blade with an external force applied to a fixing member;

FIG. 2B is a fragmentary cross-sectional view depicting the cutting blade with the fixing member in contact with a blade;

FIG. 2C is a fragmentary cross-sectional view depicting the cutting blade with the fixing member fixed on a raised portion of a hub;

FIG. 3A is a front view depicting the cutting blade;

FIG. 3B is a cross-sectional view depicting the cutting blade;

FIG. 4A is a fragmentary cross-sectional view depicting a cutting blade according to a first modification of the embodiment of the present invention, in which the cutting blade includes a hub with a raised portion inclined at an outer peripheral surface thereof;

FIG. 4B is a fragmentary cross-sectional view depicting a cutting blade according to a second modification of the embodiment of the present invention, in which the cutting blade includes a hub with a groove disposed in a raised portion;

FIG. 5 is a perspective view depicting a cutting apparatus on which the cutting blade of the present invention, specifically the cutting blade of FIG. 1, is mounted; and

FIG. 6 is an exploded perspective view depicting a cutting unit of the cutting apparatus of FIG. 5.

### DETAILED DESCRIPTION OF THE PREFERRED EMBODIMENT

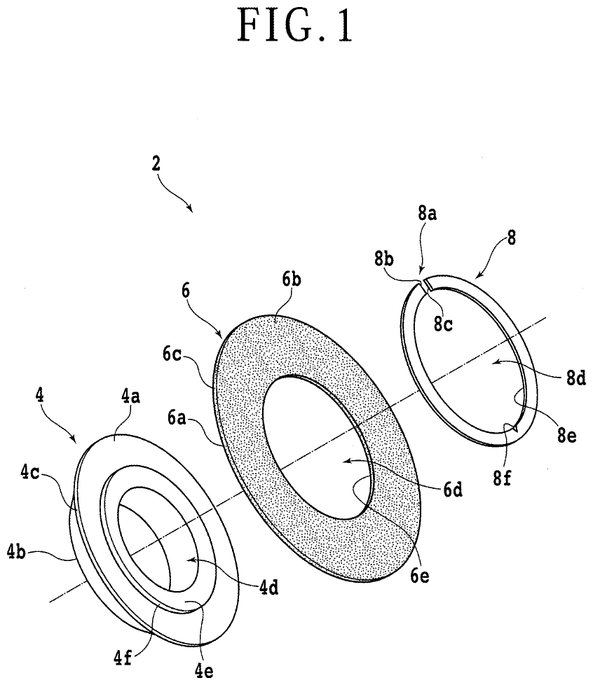

With reference to the attached drawings, an embodiment of the present invention will hereinafter be described. A description will first be made of a configuration example of a cutting blade according to this embodiment. FIG. 1 is an exploded perspective view depicting a cutting blade (hub blade) 2. The cutting blade 2 includes an annular hub 4, and an annular blade 6, and a fixing member 8, and has a structure that the hub 4 and the blade 6 are integrated together by the fixing member 8.

The hub 4 is a disk-shaped member made from a metal such as an aluminum alloy, and includes a first surface 4a and a second surface 4b which are substantially parallel to each other, and an outer peripheral edge (side surface) 4c connected to the first surface 4a. In addition, at a central portion of the hub 4, a cylindrical opening 4d is formed concentrically with the outer peripheral edge 4c, the opening 4d passing through the hub 4 in a thickness direction from the first surface 4a to the second surface 4b. On a side of the first surface 4a of the hub 4, an annular raised portion 4e is disposed protruding from the first surface 4a in the thickness direction of the hub 4. The raised portion 4e is formed with a predetermined width along a contour of the opening 4d, and includes an annular outer peripheral surface (side surface) 4f substantially perpendicular to the first surface 4a.

The blade 6 is a disk-shaped member corresponding to a washer-type cutting blade (washer blade, or hubless blade). Described specifically, the blade 6 includes abrasive grits made of diamond, cubic boron nitride (cBN), or the like, and a bonding material (binder) made of metal, ceramics, resin, or the like and fixing the abrasive grits. It is to be noted that the material and grit size of the abrasive grits, the material of the bonding material and the like are appropriately selected according to the specification of the cutting blade 2. The blade 6 includes a first surface 6a and a second surface 6b which are substantially parallel to each other, and an outer peripheral edge (side surface) 6e connected to the first surface 6a and the second surface 6b. Further, at a central portion of the blade 6, a circular opening 6d is formed concentrically with the outer peripheral edge 6c and passing through the blade 6 in a thickness direction from the first surface 6a to the second surface 6b. The opening 6d defines an inner peripheral surface (side surface) 6e of the blade 6, and the inner peripheral surface 6e is exposed inside the opening 6d.

The fixing member 8 is made from a metal such as SUS (stainless steel) or aluminum, a resin, or the like, is an annular resilient member capable of resilient deformation, and corresponds to a clip that fixes the blade 6 on the hub 4. Usable examples of the fixing member 8 include an annular leaf spring that is formed in a C-shape and can be fixed on the raised portion 4e of the hub 4.

Described specifically, the fixing member 8 is formed in an annular shape corresponding to the raised portion 4e of the hub 4, and at a portion of the fixing member 8, a cutout portion (slit) 8a is disposed extending from an outer peripheral edge to an inner peripheral surface (side surface) 8e. At the cutout portion 8a, one end portion 8b and the other end portion 8c of the fixing member 8 are arranged apart from each other such that they face each other. In other words, the fixing member 8 has a pair of end portions 8b and 8c apart from each other, and is formed in an open-loop shape. At a central portion of the fixing member 8, a circular opening 8d that passes through the fixing member 8 in a thickness direction thereof is disposed concentrically with the outer peripheral edge of the fixing member 8. The opening 8d defines the inner peripheral surface (side surface) 8e of the fixing member 8, and the inner peripheral surface 8e is exposed inside the opening 8d.

The fixing member 8 is designed such that the fixing member 8 has an inner diameter (the inner peripheral surface 8e has a diameter) equal to or smaller than an outer diameter of the raised portion 4e (a diameter of the outer peripheral surface 4f) in a state in which an external force is not applied to the fixing member 8. In addition, when an external force is applied to the fixing member 8 to make the paired end portions 8b and 8c come close to or apart from each other, the fixing member 8 undergoes resilient deformation such that its inner diameter is decreased or increased.

On a side opposite to the cutout portion 8a with respect to a center of the fixing member 8, a notched portion (indentation) 8f is preferably disposed. The notched portion 8f is formed from the inner peripheral surface 8e toward the outer peripheral edge of the fixing member 8, but does not reach the outer peripheral edge of the fixing member 8. It is to be noted that no limitations are imposed on the shape of the notched portion 8f although the notched portion 8f formed in a triangular shape as seen in plan is depicted by way of example in FIG. 1. If the notched portion 8f is formed, the fixing member 8 is narrower in width at the notched portion 8f than a width in the remaining region other than the notched portion 8f, so that the fixing member 8 is facilitated to undergo resilient deformation at the notched portion 8f. The notched portion 8f may however be omitted if the fixing member 8 can undergo sufficient resilient deformation without disposing the notched portion 8f.

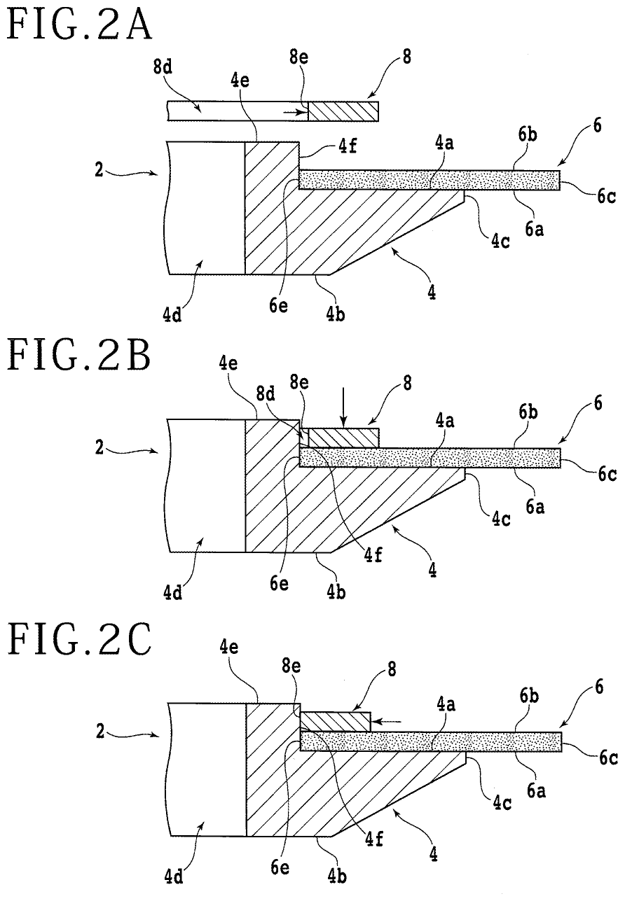

By sandwiching the blade 6 between the hub 4 and the fixing member 8, the blade 6 is fixed on the hub 4, and the cutting blade 2 is obtained accordingly. Described specifically, the first surface 6a of the blade 6 is first brought into contact with the first surface 4a of the hub 4 so that the raised portion 4e of the hub 4 is inserted in the opening 6d of the blade 6. As a consequence, the blade 6 is mounted on the hub 4 and is supported on the side of the first surface 4a of the hub 4 (see FIG. 2A).

It is to be noted that the outer diameter of the raised portion 4e (the diameter of the outer peripheral surface 4f) of the hub 4 and the inner diameter (the diameter of the inner peripheral surface 6e) of the blade 6 are preferably substantially equal to each other. In this case, upon insertion of the raised portion 4e in the opening 6d of the blade 6, the hub 4 and the blade 6 are arranged substantially concentrically with each other, so that an alignment between the hub 4 and the blade 6 is performed. However, the outer diameter of the raised portion 4e may be slightly smaller than the inner diameter of the blade 6 to facilitate the insertion of the raised portion 4e into the opening 6d of the blade 6. In this case, the difference between the outer diameter of the raised portion 4e and the inner diameter of the blade 6 is set, for example, to be smaller than 20 μm. Further, the raised portion 4e has a height greater than the thickness of the blade 6. Described specifically, the height of the raised portion 4e is set to be equal to or greater than the sum of the thickness of the blade 6 and that of the fixing member 8. The raised portion 4e therefore protrudes at a distal end portion thereof from a side of the second surface 6b of the blade 6 when the blade 6 is mounted on the hub 4 (see FIG. 2A).

With the blade 6 mounted on the hub 4, the fixing member 8 is next fixed on the distal end portion of the raised portion 4e. Described specifically, by applying an external force to the fixing member 8, the fixing member 8 is first deformed such that the inner diameter of the fixing member 8 becomes greater than the outer diameter of the raised portion 4e. For example, a worker applies a force to the fixing member 8 by the hand to have the fixing member 8 resiliently deformed so that the paired end portions 8b and 8c (see FIG. 1) separate from each other. FIG. 2A is a fragmentary cross-sectional view of the cutting blade 2 with an external force applied to the fixing member 8.

With the external force kept applied to the fixing member 8, the fixing member 8 is next brought into contact with the second surface 6b of the blade 6 such that the distal end portion of the raised portion 4e is inserted in the opening 8d of the fixing member 8. As a consequence, the fixing member 8 is arranged so as to surround the distal end portion of the raised portion 4e. FIG. 2B is a fragmentary cross-sectional view depicting the cutting blade 2 with the fixing member 8 in contact with the blade 6.

The application of the external force to the fixing member 8 is then cancelled. As a result, the inner diameter of the fixing member 8 is decreased by a resilient force (restorative force) of the fixing member 8, so that the inner peripheral surface 8e of the fixing member 8 comes into contact with the outer peripheral surface 4f of the raised portion 4e. As a consequence, the fixing member 8 grasps the distal end portion of the raised portion 4e and is fixed on the raised portion 4e, while being kept in contact with the blade 6. FIG. 2C is a fragmentary cross-sectional view depicting the cutting blade 2 with the fixing member 8 fixed on the raised portion 4e of the hub 4.

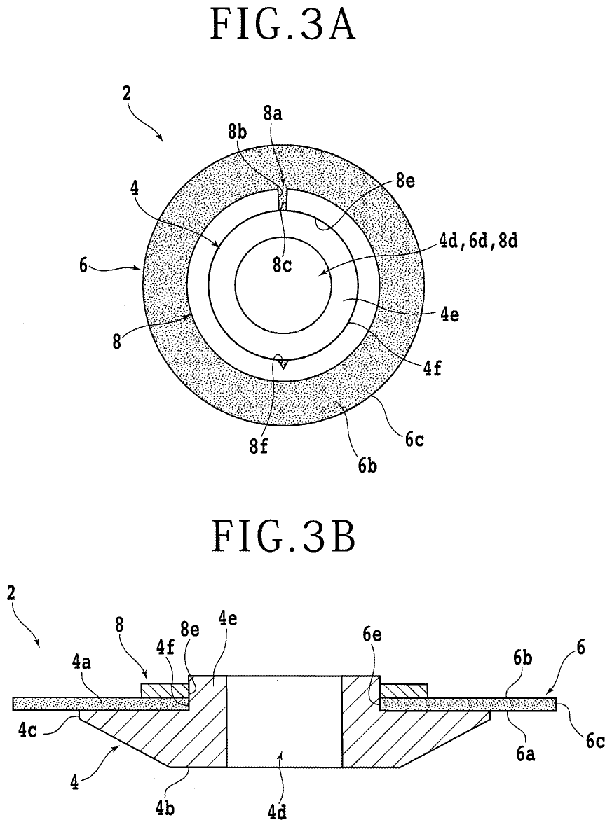

FIG. 3A is a front view depicting the cutting blade 2, and FIG. 3B is a cross-sectional view depicting the cutting blade 2. When the fixing member 8 is fixed on the raised portion 4e, the blade 6 is sandwiched between the first surface 4a of the hub 4 and the fixing member 8 and is fixed on the hub 4. It is to be noted that the blade 6 has an outer diameter (the outer peripheral edge 6c has a diameter) greater than an outer diameter of the hub 4 (a diameter of the outer peripheral edge 4c). The blade 6 therefore protrudes at an outer peripheral portion thereof from the outer peripheral edge 4c of the hub 4 outwardly in a radial direction of the hub 4 when the blade 6 is fixed on the hub 4. In this manner, the cutting blade 2 with the hub 4 and the blade 6 integrated together is obtained.

By fixing the blade 6 on the hub 4 with the fixing member 8 as described above, the hub 4 and the blade 6 can firmly be integrated together without using an adhesive. As a result, the reduction in quality of the cutting blade 2 due to running-over of an adhesive can be avoided. An adhesive may however be applied to the hub 4 or the blade 6 to assist the fixing of the blade 6 on the hub 4. For example, a small amount of an adhesive is applied to a part of the first surface 4a of the hub 4, and the hub 4 and the blade 6 are joined together via the adhesive. As a consequence, not only the fixing member 8, but also the adhesive contributes to the fixing of the blade 6, so that the hub 4 and the blade 6 are firmly integrated together. Compared with the method of the related art that integrates the hub 4 and the blade 6 together under only the action of the adhesive, the amount of the adhesive is reduced, so that the running-over of the adhesive is hard to occur.

Instead of the application of an adhesive or in addition to the application of the adhesive, the blade 6 may also be fixed on the hub 4 by use of shrinkage and expansion of the hub 4. Described specifically, provided first are the hub 4 and the blade 6 designed such that the raised portion 4e (outer peripheral surface 4f) has an outer diameter (diameter) φ₁ slightly greater than the inner diameter (diameter) φ₂ of the blade 6 (inner peripheral surface 6e). In more detail, the hub 4 and the blade 6 are adjusted in dimensions so as to satisfy φ₁>φ₂ at a predetermined temperature (hereinafter referred to as “the reference temperature”; for example, 20° C., 25° C., or the like) in the range of room temperatures (5° C. or higher and 35° C. or lower). It is to be noted that, in a shrinkage step to be mentioned below, the hub 4 is cooled to shrink such that the outer diameter φ₁ of the raised portion 4e becomes smaller than the inner diameter φ₂ of the blade 6. The difference between φ₁ and φ₂ is hence set in a range in which φ₁ can be made smaller than φ₂ by the cooling of the hub 4. If the difference between φ₁ and φ₂ is set, for example, to be smaller than 20 μm, preferably smaller than 10 μm, more preferably smaller than 5 μm, φ₁ can easily be made smaller than φ₂ in the below-mentioned shrinkage step.

The temperature of the hub 4 is next lowered to shrink the hub 4 so that the outer diameter φ₁ of the raised portion 4e becomes smaller than the inner diameter φ₂ of the blade 6 (shrinkage step). In the shrinkage step, the hub 4 is cooled to lower its temperature, for example, by storing it for a predetermined time in a refrigerator or a freezer. However, no limitations are imposed on the cooling method of the hub 4. For example, the hub 4 may be placed on a cooled support plate made from a metal, or the hub 4 may be exposed to cold air or cold water. When the hub 4 is cooled, the hub 4 shrinks in its entirety, so that the outer diameter φ₁ of the raised portion 4e decreases. The hub 4 is cooled until the outer diameter φ₁ of the raised portion 4e becomes smaller than the inner diameter φ₂ of the blade 6. This enables the raised portion 4e to be inserted into the opening 6d of the blade 6.

Cooling conditions (cooling temperature, cooling time, and so on) for the hub 4 are set according to the material and dimensions of the hub 4. For example, assume that the material of the hub 4 is A5052 (see Japanese Industrial Standards; linear expansion coefficient: 23.8×10⁻⁶/° C.) that is a type of an aluminum alloy (Al—Mg based alloy) containing magnesium, and the outer diameter φ₁ of the raised portion 4e is 40 mm. In this case, the outer diameter φ₁ of the raised portion 4e can be decreased by 20 μm or so by cooling the hub 4 and lowering the temperature of the hub 4 by 20° C. or so from the reference temperature. The raised portion 4e can therefore be inserted into the opening 6d of the blade 6 by the cooling of the hub 4 if the difference between φ₁ and φ₂ before the shrinkage of the hub 4 is smaller than 20 μm.

The raised portion 4e of the hub 4 is next inserted into the opening 6d of the blade 6 (insertion step). In the insertion step, the blade 6 is brought into contact with the first surface 4a of the hub 4 such that the raised portion 4e is inserted in the opening 6d of the blade 6. As a consequence, the blade 6 is mounted on the hub 4. It is to be noted that, at a stage immediately after the insertion of the raised portion 4e in the opening 6d of the blade 6, the outer diameter φ₁ of the raised portion 4e is smaller than the inner diameter φ₂ of the blade 6, and therefore, a slight clearance is present between the outer peripheral surface 4f of the raised portion 4e and the inner peripheral surface 6e of the blade 6.

Next, by raising the temperature of the hub 4, the hub 4 is caused to expand so as to fix the blade 6 on the hub 4 (expansion step). In the expansion step, the hub 4 is, for example, stored for a predetermined time on a support plate arranged in a room at the reference temperature. As a consequence, the temperature of the hub 4 gradually rises, the hub 4 expands in its entirety, and the outer diameter φ₁ of the raised portion 4e increases. When the hub 4 then expands until the outer diameter φ₁ of the raised portion 4e reaches the inner diameter φ₂ of the blade 6, the outer peripheral surface 4f of the raised portion 4e comes into contact with the inner peripheral surface 6e of the blade 6 and is pressed against the same. As a consequence, the blade 6 is fixed on the hub 4. It is to be noted that, in the expansion step, the hub 4 may be caused to expand by applying a heating treatment to the hub 4. For example, the hub 4 is heated by placing the hub 4 on a heated support plate made from a metal. As an alternative, the hub 4 may be exposed to warm air or warm water. This enables acceleration of the temperature rise of the hub 4, and hence, it is possible to shorten the time required for the expansion of the hub 4.

The fixing member 8 is subsequently fixed on the distal end portion of the raised portion 4e of the hub 4 as mentioned above. As a consequence, with the blade 6 fixed on the raised portion 4e, the blade 6 is further sandwiched between the hub 4 and the fixing member 8, whereby the hub 4 and the blade 6 are surely integrated together.

As described above, in the cutting blade 2 according to this embodiment, the blade 6 is sandwiched between the hub 4 and the fixing member 8 that is fixed on the raised portion 4e of the hub 4. This enables the hub 4 and the blade 6 to be firmly integrated together, while omitting or reducing an adhesive that is for fixing the blade 6 on the hub 4.

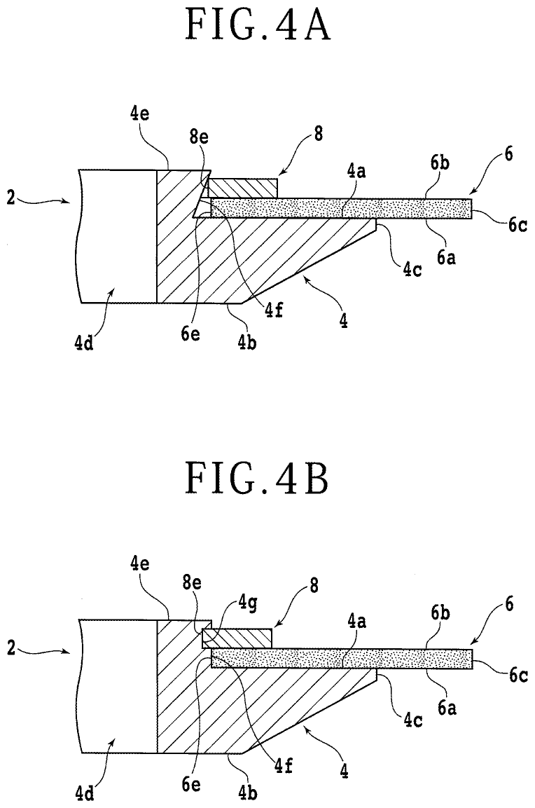

It is to be noted that the outer peripheral surface 4f of the raised portion 4e of the hub 4 may be inclined with respect to a height direction of the raised portion 4e. FIG. 4A is a fragmentary cross-sectional view depicting a cutting blade 2 according to a first modification of the embodiment of the present invention, in which the cutting blade 2 includes a hub 4 with a raised portion 4e inclined at an outer peripheral surface 4f thereof.

The raised portion 4e depicted in FIG. 4A is formed in the shape of an inverted truncated circular cone such that its diameter increases as the raised portion 4e separates farther from the first surface 4a of the hub 4. In other words, the outer peripheral surface 4f of the raised portion 4e is arranged such that its proximal end is positioned closer to a center of the raised portion 4e than its distal end. When the fixing member 8 is fixed on the raised portion 4e, an end portion of the fixing member 8 on a side of the inner peripheral surface 8e, is positioned so as to overlap the distal end portion of the raised portion 4e. As a consequence, the fixing member 8 can be prevented from moving toward the distal end portion of the raised portion 4e, and therefore, the fixing member 8 is hard to be detached from the raised portion 4e.

As a further alternative, the raised portion 4e of the hub 4 may have an annular groove in which the fixing member 8 is fitted. FIG. 4B is a fragmentary cross-sectional view depicting a cutting blade 2 according to a second modification of the embodiment of the present invention, in which a groove (recessed portion) 4g is disposed in the raised portion 4e.

The groove 4g is formed with a predetermined width from the outer peripheral surface 4f toward the center of the raised portion 4e and exposed at the outer peripheral surface 4f, as seen in cross-section. Further, the groove 4g is formed in an annular shape along the outer peripheral surface 4f so as to surround the raised portion 4e. It is to be noted that the width of the groove 4g (the length of the groove 4g in the height direction of the raised portion 4e) is set to substantially the same as the thickness of the fixing member 8 and the fixing member 8 can be inserted into the groove 4g at an edge portion thereof on the side of the inner peripheral surface 8e. Upon fixing the fixing member 8 on the raised portion 4e, the edge portion of the fixing member 8 on the side of the inner peripheral surface 8e thereof is inserted into the groove 4g, so that the fixing member 8 is partly fitted in the groove 4g. As a consequence, the fixing member 8 is sandwiched and fixed between opposite side walls (top and bottom ends) of the groove 4g, and therefore the fixing member 8 is hard to be detached from the raised portion 4e.

Also, in the above-described embodiment, the description is made of the case in which the fixing member 8 is the C-shaped resilient member (see FIG. 1). No limitations are however imposed on the shape, material, and the like of the fixing member 8 as long as it can fix the blade 6 on the hub 4. For example, the fixing member 8 may be a member of an annular shape (closed loop shape) free of the cutout portion 8a. Described specifically, an annular rubber member, the diameter of which is changeable through resilient deformation, or the like can also be used as the fixing member 8.

Moreover, using shrinkage and expansion of the hub 4, the fixing member 8 free of the cutout portion 8a can also be fixed on the raised portion 4e. Described specifically, the fixing member 8 has an inner diameter (the diameter of the inner peripheral surface 8e) set to substantially the same as the outer diameter of the raised portion 4e (the diameter of the outer peripheral surface 4f). After the above-described shrinkage step and insertion step, the fixing member 8 is then mounted on the raised portion 4e such that the raised portion 4e is inserted in the opening 8d of the fixing member 8. Subsequently, the above-described expansion step is performed to cause the hub 4 to expand. As a consequence, the outer diameter of the raised portion 4e increases so that the outer peripheral surface 4f of the raised portion 4e comes into contact with the inner peripheral surface 6e of the blade 6 and the inner peripheral surface 8e of the fixing member 8 and is pressed against the same. The fixing member 8 is therefore fixed on the raised portion 4e of the hub 4.

Further, using shrinkage and expansion of the fixing member 8, the fixing member 8 free of the cutout portion 8a can also be fixed on the raised portion 4e. Described specifically, the fixing member 8 has an inner diameter set to a value slightly smaller than the outer diameter of the raised portion 4e. By raising the temperature of the fixing member 8, the fixing member 8 is first caused to expand until the inner diameter of the fixing member 8 becomes greater than the outer diameter of the raised portion 4e. The fixing member 8 is then mounted on the raised portion 4e such that the raised portion 4e is inserted in the opening 8d of the fixing member 8. Subsequently, by lowering the temperature of the fixing member 8, the fixing member 8 is caused to shrink until the inner peripheral surface 8e of the fixing member 8 comes into contact with the outer peripheral surface 4f of the raised portion 4e. As a consequence, the fixing member 8 is fixed on the hub 4.

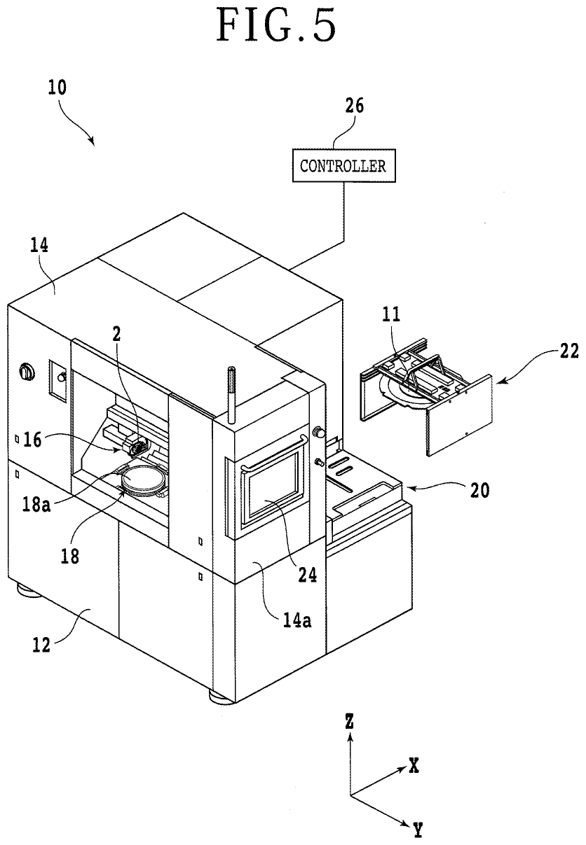

The cutting blade 2 according to this embodiment is mounted on a cutting apparatus and is used for cutting a workpiece. FIG. 5 is a perspective view depicting a cutting apparatus 10 that cuts a workpiece 11. In FIG. 5, an X-axis direction (a processing feed direction, a left-right direction, or a first horizontal direction) and a Y-axis direction (an indexing feed direction, a front-rear direction, or a second horizontal direction) are directions perpendicular to each other. Further, a Z-axis direction (a height direction, an up-down direction, or a vertical direction) is a direction perpendicular to the X-axis direction and Y-axis direction.

The workpiece 11 is, for example, a disk-shaped wafer made from a semiconductor material such as silicon. The workpiece 11 is defined into a plurality of rectangular or square regions by a plurality of streets (scribe lines) arrayed in a grid pattern such that the streets intersect together. In the regions defined by the streets, devices such as integrated circuits (ICs), large scale integrations (LSIs), light emitting devices (LEDs), or micro electro mechanical systems (MEMS) devices are formed, respectively. By cutting and dividing the workpiece 11 along the streets with the cutting apparatus 10, a plurality of device chips are manufactured including the respective devices.

No limitations are however imposed on the material, shape, structure, size, and the like of the workpiece 11. For example, the workpiece 11 may be a substrate made from a semiconductor other than silicon (GaAs, InP, GaN, SiC, or the like), glass, ceramics, resin, metal, or the like. No limitations are imposed either on the kind, number, shape, structure, size, arrangement, and the like of the devices, and no devices may be formed on the workpiece 11. Further, the workpiece 11 may be a package substrate such as a chip size package (CSP) substrate or a quad flat non-leaded package (QFN) substrate. For example, a package substrate is formed by covering and encapsulating, with a resin layer (mold resin), a plurality of device chips mounted on a mount substrate. A plurality of package devices each including packaged device chip are manufactured by dividing the package substrate to singulate it into individual pieces.

The cutting apparatus 10 includes a bed 12 which supports or accommodates individual elements that make up the cutting apparatus 10. Above the bed 12, a cover 14 is disposed covering the bed 12 on a side of a top wall thereof. Inside the cover 14, there is disposed a space (processing chamber) in which processing of the workpiece 11 is to be performed. Disposed in the processing chamber is a cutting unit 16 on which the cutting blade 2 is mounted. Ball screw type moving mechanisms (not depicted) are coupled with the respective cutting unit 16 to move the cutting unit 16 along the Y-axis direction and Z-axis direction.

Below the cutting unit 16, a chuck table (holding table) 18 is disposed to hold the workpiece 11. The chuck table 18 has an upper surface which is a planar surface substantially parallel to a horizontal plane (X-Y plane) and makes up a holding surface 18a on which the workpiece 11 is to be held. The holding surface 18a is connected to a suction source (not depicted) such as an ejector via a flow path (not depicted) formed inside of the chuck table 18, a valve (not depicted), and the like. When a suction force (negative pressure) of the suction source is caused to act on the holding surface 18a with the workpiece 11 placed on the holding surface 18a, the workpiece 11 is held by suction on the chuck table 18.

A further ball screw type moving mechanism (not depicted) is coupled with the chuck table 18 to move the chuck table 18 along the X-axis direction. A rotary drive source (not depicted) such as a motor is also coupled with the chuck table 18 to rotate the chuck table 18 about an axis of rotation which is substantially parallel to the Z-axis direction.

At a front corner section of the bed 12, a cassette elevator 20 is disposed. On the cassette elevator 20, a cassette 22 in which a plurality of workpieces 11 can be accommodated is arranged. The cassette elevator 20 adjusts the height of the cassette 22 such that unloading of each workpiece 11 from the cassette 22 and loading of the workpiece 11 into the cassette 22 can appropriately be performed. In a vicinity of the cassette elevator 20, a transfer mechanism (not depicted) is also disposed to transfer each workpiece 11. The transfer mechanism transfers the workpiece 11 between the chuck table 18 and the cassette 22.

On a side of a front wall 14a of the cover 14, a display unit (a display section, or a display device) 24 is disposed to display various pieces of information regarding the cutting apparatus 10. As the display unit 24, a display of the touch screen type is used, for example. In this case, the display unit 24 also functions as an input section (an input unit, or an input device) for inputting various pieces of information to the cutting apparatus 10, and an operator can input information such as processing conditions to the cutting apparatus 10 through touch operations on the display unit 24. In other words, the display unit 24 functions as a user interface.

Individual elements (the cutting unit 16, the chuck table 18, the cassette elevator 20, the display unit 24, and the like) which make up the cutting apparatus 10 are connected to a controller (a control unit, a control section, or a control device) 26. The controller 26 controls operations of the cutting apparatus 10 by outputting control signals to the individual elements of the cutting apparatus 10. For example, the controller 26 is configured by a computer, and includes a processing section that performs processing required for operating the cutting apparatus 10, and a storage section that stores various pieces of information (data, programs, and so on) to be used in operating the cutting apparatus 10. The processing section includes a processor such as a central processing unit (CPU). Also, the storage section includes a memory such as a read only memory (ROM) or a random access memory (RAM).

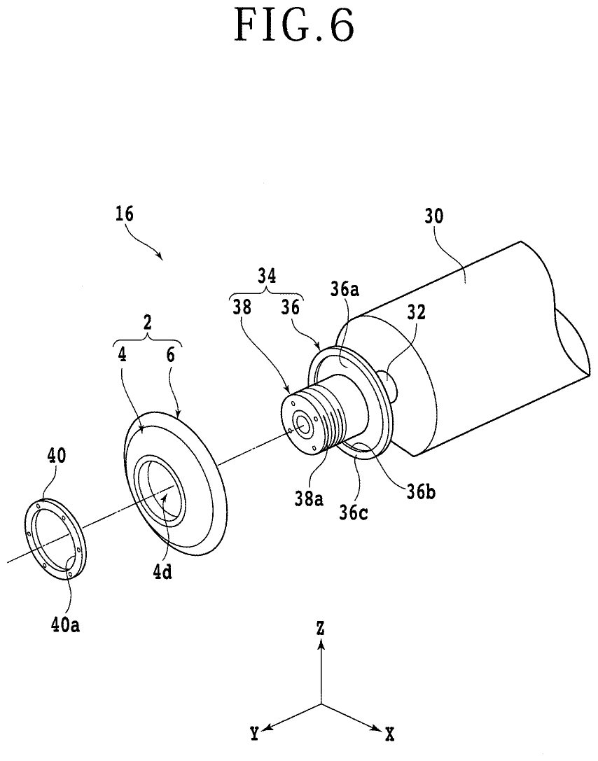

FIG. 6 is an exploded perspective view depicting the cutting unit 16. The cutting unit 16 includes a cylindrical housing 30, and a rod-shaped spindle 32 arranged along the Y-axis direction is accommodated in the housing 30. The spindle 32 is exposed at a distal end portion thereof (one end portion thereof) to an outside of the housing 30. With a proximal end portion (to the other end portion) of the spindle 32, on the other hand, a rotary drive source (not depicted) such as a motor is coupled.

On the distal end portion of the spindle 32, a blade mount 34 is fixed. The blade mount 34 includes a disk-shaped flange portion 36, and a rod-shaped boss portion (support shaft) 38 extending from a central portion of a surface 36a of the flange portion 36. On a side of the surface 36a of an outer peripheral portion of the flange portion 36, an annular raised portion 36b is disposed protruding from the surface 36a. A distal surface of the raised portion 36b is a planar surface substantially parallel to the surface 36a, and makes up a support surface 36c to support the cutting blade 2. On an outer peripheral surface of a distal end portion of the boss portion 38, an externally threaded portion (thread groove) 38a is formed.

An annular fixture nut 40 is fastened on the externally threaded portion 38a of the boss portion 38. At a central portion of the fixture nut 40, a circular opening 40a is disposed extending through the fixture nut 40 in a thickness direction thereof. The opening 40a is formed with substantially the same diameter as that of the boss portion 38. On an inner peripheral surface of the fixture nut 40 exposed in the opening 40a, an internally threaded portion (thread groove) is disposed corresponding to the externally threaded portion 38a of the boss portion 38.

When the cutting blade 2 is positioned so as to insert the boss portion 38 in the opening 4d of the hub 4, the cutting blade 2 is mounted on the blade mount 34. In this state, the fixture nut 40 is fastened on the externally threaded portion 38a of the boss portion 38, whereby the cutting blade 2 is sandwiched between the support surface 36c of the flange portion 36 and the fixture nut 40. In this manner, the cutting blade 2 is fixed on the distal end portion of the spindle 32.

The cutting blade 2 is rotated about an axis of rotation, which is substantially parallel to the Y-axis direction, by power transmitted from the rotary drive source via the spindle 32 and the blade mount 34. By causing the cutting blade 2 to cut into the workpiece 11 held on the chuck table 18 (see FIG. 5) with the cutting blade 2 kept rotating, the workpiece 11 is cut.

It is to be noted that the structures, methods, and the like according to the above-described embodiment can be practiced with changes or modifications as needed to such an extent as not departing from the scope of the object of the present invention.

The present invention is not limited to the details of the above-described preferred embodiment. The scope of the invention is defined by the appended claims and all changes and modifications as fall within the equivalence of the scope of the claims are therefore to be embraced by the invention.

What is claimed is:

1. A cutting blade comprising:
a hub having a raised portion;
an annular blade having an opening with the raised portion inserted therein; and
an annular fixing member fixing the blade on the hub,
wherein the blade is sandwiched between the hub and the fixing member that is fixed on the raised portion.

2. The cutting blade according to claim 1,
wherein the raised portion includes a groove with the fixing member fitted therein.

3. The cutting blade according to claim 1,
wherein the fixing member is an annular resilient member having a pair of end portions that are apart from each other.
